(19) United States
(12) Patent Application Publication
(10) Pub. No.: US 2006/0008036 A1
(43) Pub. Date: Jan. 12, 2006

(54) Receiving method and receiving apparatus

(75) Inventor: Shinsuke Moriai, Inuyama-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD., Osaka (JP)

(21) Appl. No.: 11/204,172

(22) Filed: Aug. 16, 2005

Related U.S. Application Data
(63) Continuation of application No. PCT/JP04/16757, filed on Nov. 11, 2004.

(30) Foreign Application Priority Data
Nov. 20, 2003 (JP) 2003-391293
Nov. 20, 2003 (JP) 2003-391294

(51) Int. Cl. H03D 1/00

(52) U.S. Cl. 375/343

(57) ABSTRACT

One correlation value is selected with high accuracy from among a plurality of correlation values which have been subjected to Walsh transform. A Fast Walsh Transform (FWT) computing unit performs an FWT computation on CCK-modulated signals and outputs 64 Walsh transform values. A maximum value search unit inputs 64 Walsh transform values, and then based on the magnitude thereof it outputs a first phase correlation value signal and a first phase index signal both corresponding to one FWT value. A second phase signal derivation unit inputs the first phase index signal and outputs a second phase index signal and a second phase correlation value signal. A phase signal determining unit performs differential detection on the first phase correlation value signal and the second phase correlation value signal, respectively, for the signals which have already been outputted. The results of the differential detection are respectively compared with the phases prior to differential coding, and one having less error is selected.

This is a continuation of International Application PCT/JP2003/016757, filed Nov. 11, 2004.

### BACKGROUND OF THE INVENTION

1. Field of the Invention

The present invention generally relates to the receiving technologies, and it particularly relates to method and apparatus for receiving signals which have been subjected to the spectrum spreading.

2. Description of the Related Art

As a spread spectrum communication system using the radio frequency of 2.4 GHz band, the wireless LAN (Local Area Network) of IEEE802.11b standard has been developed and put to practical use. This wireless LAN realizes the maximum transmission rate of 11 Mbps by CCK (Complementary Code Keying) modulation. Since the bandwidth of wireless LAN is set to 26 MHz by the Radio Law, the upper limit of chip rate in the direct sequence scheme is also 26 Mcps. However, if the chip rate of 26 Mcps is band-limited by an ideal Nyquist filter, the sampling frequency of a D-A converter becomes 40 MHz. And in this case, a steep band-limiting is also needed and thus this is not so realistic. Hence, instead of the band-limiting by the Nyquist filter, the baseband signal is actually band-limited by the analog filter after D-A conversion, so that the chip rate is approximately 11 Mcps maximum. In such receiving apparatus compatible with the CCK modulation, a plurality of patterns of transmitted signal waveforms are generally prepared in advance, and the transmitted signal whose waveform approximates closest to the waveform of a received signal is regarded as a modulation result (see, for instance, Reference (1) in the following Related Art List).

### RELATED ART LIST

(1) Japanese Patent Application Laid-Open No. 2003-168999.

The receiving apparatus receives signals in which a combination composed of a plurality of signals has been CCK-modulated, and performs Fast Walsh Transform (FWT) on the thus received signals so as to derive a plurality of correlation values. The receiving apparatus then selects a correlation value whose value is the largest from among the plurality of correlation values, and recovers the signals. However, if errors are contained in the correlation values obtained through the FWT computation due to the effects of noise and multipath transmission, there may be cases where the incorrect combination composed of a plurality of signals is selected by mistake. Under these circumstances the inventor of the present invention came to recognize the following problems. In a situation where the combination composed of a plurality of signals is mistakingly selected, there are cases where one of a plurality of phase signals contained in the combination of signals is wrong. Moreover, if the plurality of phase signals contained in the combination of signals are respectively phase-modulated, that is, if, for example, they are modulated by the phase modulation scheme of QPSK (Quadrature Phase Shift Keying), then there are cases where the phase of the above single erroneous phase signal is deviated by ±π/2 from the correct phase signal. Furthermore, in the situation where the combination composed of a plurality of signals is mistakingly selected, there are cases where another combination, composed of a plurality of signal, whose magnitude of correlation value is the second largest, happens to be the correct combination. That is, there may be a case where a combination composed of a plurality of signals, whose magnitude of correlation value shall theoretically be the largest, becomes the second largest in the magnitude of correlation value, instead.

### SUMMARY OF THE INVENTION

The present invention has been made in view of the foregoing circumstances and problems and an objective thereof is to provide a receiving technique by which to estimate, with high accuracy, the transmitted signals from the Walsh-transformed results.

A preferred mode of carrying out the present invention relates to a receiving apparatus. This apparatus comprises: a receiver which receives a signal indicative of at least one symbol including a plurality of Walsh codes wherein the plurality of Walsh codes are generated based on a combination composed of a plurality of phase signals that contain differentially coded phase signals; a Walsh transform unit which performs Walsh transform on the signal received by the receiver for each symbol and which then generates a plurality of correlation values; a first derivation unit which selects a single correlation value based on the magnitude of the plurality of correlation values generated by the Walsh transform unit and which derives, as a first phase signal, a combination composed of a plurality of phase signals corresponding to the selected correlation value; a second derivation unit which derives, as a second phase signal, a combination composed of a plurality of phase signals other than a plurality of phase signals corresponding to the first phase signal; and an output unit which outputs the plurality of phase signals corresponding to either the first phase signal or second phase signal, based on the differentially coded phase signals contained respectively in the first phase signal derived by the first derivation unit and the second phase signal derived by the second derivation unit.

By employing the above apparatus, the derived first phase signal and second phase signal are generated by repeating a correlation processing a plurality of times, so that the power of signal is amplified. And the differential detection is carried out with said power being amplified and then the first phase signal or the second phase signal is selected using relative values obtained as a result of such the differential detection, so that the accuracy in selecting the phase signal is improved.

Another preferred mode of carrying out the present invention relates also to a receiving apparatus. This apparatus comprises: a receiver which receives a signal indicative of at least one symbol including a plurality of Walsh codes wherein the plurality of Walsh codes are generated based on a combination composed of a plurality of phase signals that contain differentially coded phase signals; a Walsh transform unit which performs Walsh transform on the signal received by the receiver for each symbol and which then generates a plurality of correlation values; a first derivation unit which selects a single correlation value based on the magnitude of the plurality of correlation values generated by the Walsh transform unit and which derives, as a first phase signal, a combination composed of a plurality of phase signals corresponding to the selected correlation value; a second derivation unit which derives, as a second phase signal, a combination composed of a plurality of phase signals other than a plurality of phase signals corresponding to the first phase signal, based on the first phase signal derived by the first derivation unit; and an output unit which outputs the plurality of phase signals corresponding to either the first phase signal or second phase signal, based on the differentially coded phase signals contained respectively in the first phase signal derived by the first derivation unit and the second phase signal derived by the second derivation unit.

By employing this apparatus, the derived first phase signal and second phase signal are generated by repeating a correlation processing a plurality of times, so that the power of signal is amplified. And the differential detection is carried out with said power being amplified and then the first phase signal or the second phase signal is selected using relative values obtained as a result of such the differential detection, so that the accuracy in selecting the phase signal is improved.

The second derivation unit may comprises: a candidate generating unit which rotates any of phase of a plurality of phase signals other than the differentially coded phase signals, among the combination composed of a plurality of phase signals corresponding to the first phase signal derived by the first derivation unit and which generates a plurality of candidates for the second phase signal by changing a phase signal, whose phase is to be rotated, among the plurality of phase signals; and a selector which selects the second phase signal based on the magnitude of correlation values corresponding respectively to the plurality of generated candidates for the second phase signal.

The candidate generating unit may rotate a phase of the phase signal, whose phase is to be rotated, to a phase adjacent to a primarily assigned phase among a plurality of phases to which a phase signal is possibly assigned, and then generate a candidate for the second phase signal.

The “primarily assigned phase” is a theoretically determined one and in the case of QPSK, for example, it corresponds to 0, π/2, π and 3π/2. That is, it corresponds to the phase at which the signal is allotted in a transmission side.

The apparatus may further comprise a managing unit which manages the combination composed of a plurality of phase signals by an identification number, wherein the first derivation unit may derive from the managing unit an identification number corresponding to the first phase signal and wherein the second derivation unit may derive from the managing unit an identification number corresponding to the second phase signal, based on the derived identification number corresponding to the first phase signal. The output unit may output a plurality of phase signals corresponding to the first phase signal if a difference between the magnitude of a correlation value corresponding to the derived first phase signal and that corresponding to the derived second phase signal is greater than or equal to a predetermined threshold value.

The output unit may include: a differential detection unit which respectively performs differential detection on differentially coded phase signal among a plurality of phase signals outputted in the past from the output unit for differentially coded phase signals contained in the first phase signal derived by the first derivation unit and the second phase signal derived by the second derivation unit, respectively; and a comparator which compares differential detection results and selects either the first phase signal or the second phase signal. The comparator may perform differential detection on differentially coded phase signals in the derived first phase signal and the derived second phase signal, compare the differential detection result with a phase to which a signal is possibly assigned, and select either the first phase signal or the second phase signal.

Still another preferred mode of carrying out the present invention relates also to a receiving apparatus. This apparatus comprises: a receiver which receives a signal indicative of at least one symbol including a plurality of Walsh codes wherein the plurality of Walsh codes are generated based on a combination composed of a plurality of phase signals that contain differentially coded phase signals; a Walsh transform unit which performs Walsh transform on the signal received by the receiver for each symbol and which then generates respectively a plurality of correlation values; a first derivation unit which selects a single correlation value based on the magnitude of the plurality of correlation values generated by the Walsh transform unit and which derives, as a first phase signal, a combination composed of a plurality of phase signals corresponding to the selected correlation value; a second derivation unit which derives, as a second phase signal, a combination composed of a plurality of phase signals other than a plurality of phase signals corresponding to the first phase signal, based on the magnitude of the plurality of correlation values generated by the Walsh transform unit; and an output unit which outputs the plurality of phase signals corresponding to either the first phase signal or second phase signal, based on the differentially coded phase signals contained respectively in the first phase signal derived by the first derivation unit and the second phase signal derived by the second derivation unit.

By employing this apparatus, the derived first phase signal and second phase signal are generated by repeating a correlation processing a plurality of times, so that the power of signal is amplified. And the differential detection is carried out with said power being amplified and then the first phase signal or the second phase signal is selected using relative values obtained as a result of such the differential detection, so that the accuracy in selecting the phase signal is improved.

The first derivation unit may select a correlation value whose magnitude is maximum among the plurality of correlation values generated by the Walsh transform unit and derive, as the first phase signal, a combination composed of a plurality of phase signals corresponding to the selected correlation value, and it may select a correlation value whose magnitude is largest next to the correlation value selected by the first derivation unit among the plurality of correlation values generated by the Walsh transform unit and derive, as the second phase signal, a combination composed of a plurality of phase signals corresponding to the selected correlation value. The second derivation unit may select a correlation value whose magnitude is greater than or equal to a predetermined threshold value and derives, as the second phase signal, a combination composed of a plurality of phase signals corresponding to the selected value. The output unit may output a plurality of phase signals corresponding to the first phase signal if a difference between the magnitude of a correlation value corresponding to the derived first phase signal and that corresponding to the derived second phase signal is greater than or equal to a predetermined threshold value.

The output unit may include: a differential detection unit which respectively performs differential detection on differentially coded phase signal among a plurality of phase signals outputted in the past from the output unit for differentially coded phase signals contained in the first phase signal derived by the first derivation unit and the second phase signal derived by the second derivation unit, respectively; and a comparator which compares differential detection results and selects either the first phase signal or the second phase signal. The comparator may perform differential detection on differentially coded phase signals in the derived first phase signal and the derived second phase signal, compare the differential detection result with a phase to which a signal is possibly assigned, and select either the first phase signal or the second phase signal.

Still another preferred mode of carrying out the present invention relates to a receiving method. This method comprises: receiving a signal indicative of at least one symbol including a plurality of Walsh codes wherein the plurality of Walsh codes are generated based on a combination composed of a plurality of phase signals that contain differentially coded phase signals; performing Walsh transform on the signal received by the receiving for each symbol and generating respectively a plurality of correlation values; selecting a single correlation value based on the magnitude of the plurality of correlation values generated by the performing and generating, and deriving, as a first phase signal, a combination composed of a plurality of phase signals corresponding to the selected correlation value; deriving, as a second phase signal, a combination composed of a plurality of phase signals other than a plurality of phase signals corresponding to the first phase signal; and outputting the plurality of phase signals corresponding to either the first phase signal or second phase signal, based on the differentially coded phase signals contained respectively in the first phase signal derived by the selecting and deriving and the second phase signal derived by the deriving.

Still another preferred mode of carrying out the present invention relates also to a receiving method. This method comprises: receiving a signal indicative of at least one symbol including a plurality of Walsh codes wherein the plurality of Walsh codes are generated based on a combination composed of a plurality of phase signals that contain differentially coded phase signals; performing Walsh transform on the signal received by the receiving for each symbol and generating respectively a plurality of correlation values; selecting a single correlation value based on the magnitude of the plurality of correlation values generated by the performing and generating, and deriving, as a first phase signal, a combination composed of a plurality of phase signals corresponding to the selected correlation value; deriving, as a second phase signal, a combination composed of a plurality of phase signals other than a plurality of phase signals corresponding to the first phase signal, based on the first phase signal derived by the selecting and deriving; and outputting the plurality of phase signals corresponding to either the first phase signal or second phase signal, based on the differentially coded phase signals contained respectively in the first phase signal derived by the selecting and deriving and the second phase signal derived by the deriving.

Still another preferred mode of carrying out the present invention relates also to a receiving method. This method comprises: receiving a signal indicative of at least one symbol including a plurality of Walsh codes wherein the plurality of Walsh codes are generated based on a combination composed of a plurality of phase signals that contain differentially coded phase signals; performing Walsh transform on the signal received by the receiving for each symbol and generating respectively a plurality of correlation values; selecting a single correlation value based on the magnitude of the plurality of correlation values generated by the performing and generating, and deriving, as a first phase signal, a combination composed of a plurality of phase signals corresponding to the selected correlation value; deriving, as a second phase signal, a combination composed of a plurality of phase signals other than a plurality of phase signals corresponding to the first phase signal, based on the magnitude of the plurality of correlation values generated by the performing and generating; and outputting the plurality of phase signals corresponding to either the first phase signal or second phase signal, based on the differentially coded phase signals contained respectively in the first phase signal derived by the selecting and deriving and the second phase signal derived by the deriving.

It is to be noted that any arbitrary combination of the above-described structural components as well as the expressions according to the present invention changed among a method, an apparatus, a system, a recording medium, a computer program and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

FIG. 1 illustrates a burst format of a communication system according to a first embodiment of the present invention.

FIG. 2 illustrates a structure of a communication system according to the first embodiment of the present invention.

FIG. 3 illustrates a structure of a baseband processing unit shown in FIG. 2.

FIG. 4 illustrates a structure of an FWT computing unit shown in FIG. 3.

FIG. 5 illustrates a structure of a first φ2 estimation unit shown in FIG. 4.

FIG. 6 illustrates a structure of a maximum value search unit shown in FIG. 3.

FIG. 7 illustrates a data structure of index which is set beforehand in a maximum value index storage shown in FIG. 6.

FIG. 8 illustrates a structure of a second phase signal derivation unit shown in FIG. 3.

FIG. 9 shows the first to sixth candidates generated by a candidate generating unit shown in FIG. 8.

FIG. 10 illustrates a structure of a phase signal determining unit shown in FIG. 3.

FIG. 11 illustrates an operation scheme of a comparator shown in FIG. 10.

FIG. 12 illustrates a structure of a baseband processing unit according to a second embodiment of the present invention.

FIG. 13 illustrates an operation scheme of a decision unit shown in FIG. 12.

FIG. 14 illustrates a structure of a baseband processing unit according to a third embodiment of the present invention.

### DETAILED DESCRIPTION OF THE INVENTION

The invention will now be described based on the following embodiments which do not intend to limit the scope of the present invention but exemplify the invention. All of the features and the combinations thereof described in the embodiments are not necessarily essential to the invention.

### First Embodiment

Before describing the present invention in a specific manner, an outline of the present invention will be described first. A first embodiment according to the present invention relates to a receiving apparatus of wireless LAN system that conforms to the IEEE802.11b standard. A receiving apparatus according to the present embodiments receives signals in which a combination composed of a plurality of phase signals have been subjected to CCK modulation, and then derives a plurality of correlation values through an FWT computation. Then the receiving apparatus selects from among the plurality of correlation values a correlation value whose magnitude is the largest, and derives a combination of correlation signals corresponding to the thus selected correlation value. Hereinafter, the selected combination of correlation signals will be referred to as “first phase signal”. The combination of correlation signals contains four phase signals one of which is differentially coded. The remaining phase signals in the combination are respectively QPSK modulated. Hereinafter these remaining phase signals will be collectively referred to as, or one of these phase signals will be referred to as “spread code signal”. The receiving apparatus according to the present embodiment rotates one of the spread code signals contained in the first phase signal, by +π/2 or −π/2. While it is changing the signal to be rotated in the spread code signals, the receiving apparatus generates six kinds of combinations of phase signals (hereinafter the respective combinations will be referred to as “first candidate” to “sixth candidate”) and selects, from among these combinations, one whose correlation value is the largest (hereinafter one combination selected among from the six kinds of combinations of phase signals will be referred to as “second phase signal”).

If a difference between a correlation value corresponding to the first phase signal and that corresponding to the second phase signal is greater than or equal to a threshold value, the differentially coded signal contained in the first phase is subjected to differential detection, and the signal which has been subjected to the differential detection and the spread code signal contained in the first phase signal are outputted. If, on the other hand, the difference between a correlation value corresponding to the first phase signal and that corresponding to the second phase signal is smaller than the threshold value, the signals respectively contained in the first phase signal and the second phase signal are subjected to the differential detection, so that two kinds of the differential detection results are obtained. If a phase in which the differential detection result is possibly assigned, for example, if the differential QPSK modulation is used as a differential coding, errors between each of the two kinds of differential detection results and any one of 0, π/2, π and 3π/2 (these phases will be hereinafter referred to as “phases prior to differential coding”) are respectively calculated. Among the thus calculated two kinds of errors, the first phase signal or the second phase signal corresponding to the error which is less than the other is selected. Finally, a spread code signal and a differential detection signal both corresponding to the thus selected phase signal are outputted.

An outline of CCK modulation in the IEEE802.11b will be described since this scheme is assumed, for example, in the present embodiments. In the CCK modulation, 8 bits constitute one unit (hereinafter this unit will be referred to as “CCK modulation unit”) and these 8 bits are called d1, d2, . . . , d8 counted from the highest order. The lower-order 6 bits are respectively mapped to constellations of QPSK in units of [d3, d4], [d5, d6] and [d7, d8] among the CCK modulation units. The thus mapped phases will be indicated respectively by (φ2, φ3, φ4). Eight kinds of spread codes P1 to P8 are generated from the phases φ2, φ3 and φ4, as follows:
P1=φ2+φ3+ 4
P2=φ3+φ4
P3=φ2+φ4
P4=φ4
P5=φ2+φ3
P6=φ3
P7=φ2
P8=0 (Equations 1)

On the other hand, the higher-order 2 bits [d1, d2] among the CCK modulation-units are mapped to a constellation of DQPSK (Differential encoding Quadrature Phase Shift Keying), and it is assumed here that the thus mapped phase is φ1. From φ1 and the spread codes P1 to P8, the following 8 ways of chip signals, namely, X0 to X7 are generated.
X0=e^{j}(φ1+P1)
X1=e^{J}(φ1+P2)
X2=e^{j}(φ1+P3)
X3=−e^{j}(φ1+P4)
X4=e^{j}(φ1+P5)
X5=e^{j}(φ1+P6)
X6=−e^{j}(φ1+P7)
X7=e^{j}(φ1+P8) (Equations 2)

A transmitting apparatus transmits the chip signals in the order of X0 to X7 (hereinafter the unit of time sequence constituted by chip signals X0 to X7 will be referred to “CCK modulation unit”, too).

It is to be noted that in the IEEE802.11b the phase-modulated signals of DBPSK or DQPSK, in addition to the CCK modulation, are spread by known spread codes and then transmitted.

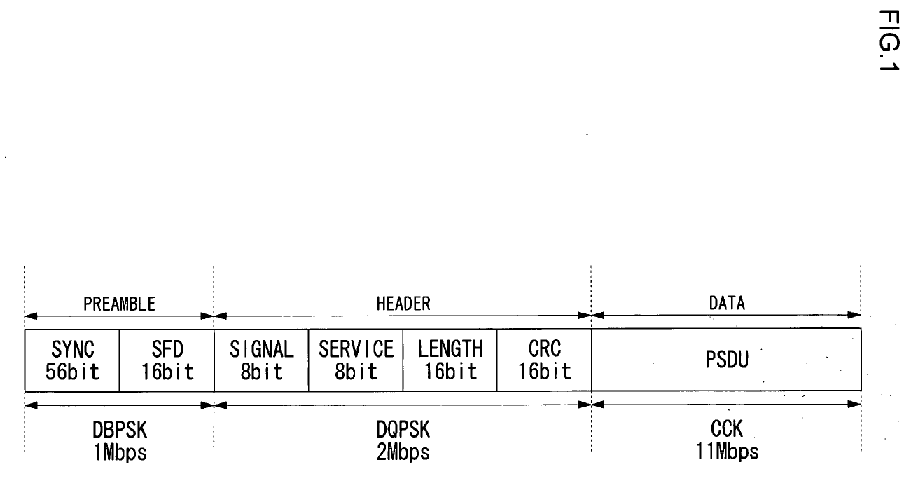

FIG. 1 illustrates a burst format according to the first embodiment of the present invention. This burst format corresponds to ShortPLCP of IEEE802.11b standard. As shown in FIG. 1, the burst signal includes a preamble, a header and a data region. The preamble is communicated by a modulation scheme of DBPSK at a transmission rate of 1 Mbps, the header is communicated by a modulation scheme of DQPSK at a transmission rate of 2 Mbps, and the data is communicated by a modulation scheme of CCK at a transmission rate of 11 Mbps. The preamble includes 56-bit SYNC and 16-bit SFD, and the header includes 8-bit SIGNAL, 8-bit SERVICE, 16-bit LENGTH and 16-bit CRC. On the other hand, the length of PSDU that corresponds to the data is variable.

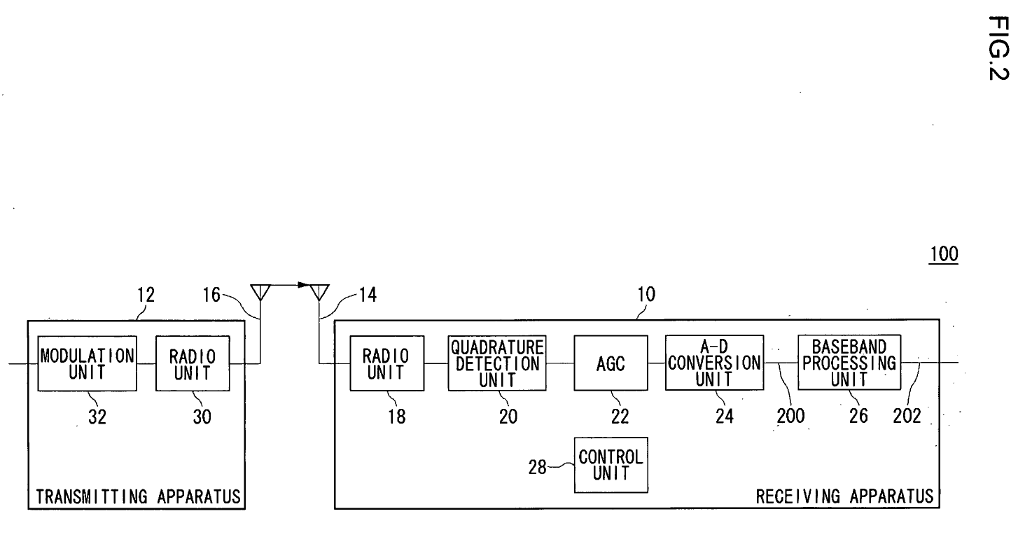

FIG. 2 illustrates a structure of a communication system 100 according to the first embodiment of the present invention. The communication system 100 includes a receiving apparatus 10 and a transmitting apparatus 12. The receiving apparatus includes a receiving antenna 14, a radio unit 18, a quadrature detection unit 20, an AGC (Automatic Gain Control) 22, an A-D conversion unit 24, a baseband processing unit 26 and a control unit 28. The transmitting apparatus 12 includes a transmitting antenna 16, a radio unit 30 and a modulation unit 32. Signals involved here include a digital received signal 200 and an output signal 202.

The modulation unit 32 performs CCK modulation on information to be transmitted or performs spread processing on the signals which have been phase-modulated. The radio unit 30 carries out frequency conversion between baseband signals outputted from the modulation unit 32 and radio-frequency (RF) signals and amplification processing. The transmitting antenna 16 transmits the radio-frequency signals, and the receiving antenna 14 received the radio-frequency signals.

The radio unit 18 frequency-converts the received RF signals into intermediate-frequency (IF) signals. The quadrature detection unit 20 performs quadrature detection on the IF signals and outputs baseband signals. Though the baseband signals are generally represented by two components which are in-phase components and quadrature components, they are drawn and depicted herein as a single entity. The AGC 22 automatically controls gain so that the amplitudes of baseband signals lie within a dynamic range of the A-D conversion unit 24 described later. The A-D conversion unit 24 converts a baseband analog signal into a digital signal and outputs a digital received signal 200 composed of a plurality of bits. The baseband processing unit despreads or demodulates the digital received signal 200 so as to output an output signal 202. The control unit 28 controls timing and the like of the receiving apparatus 10.

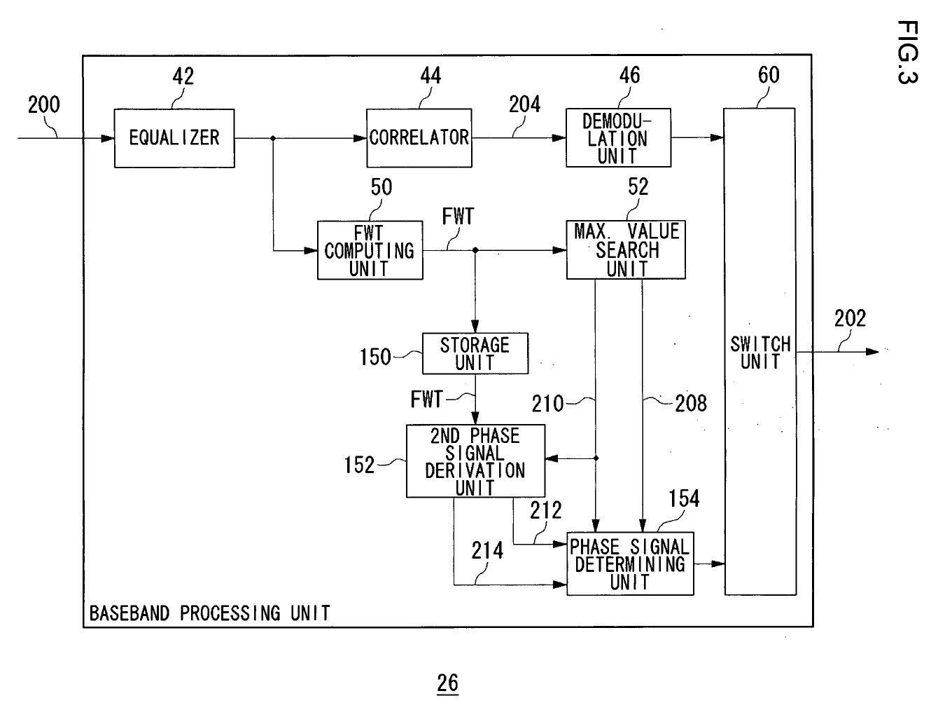

FIG. 3 illustrates a structure of a baseband processing unit 26. The baseband processing unit 26 includes an equalizer 42, a correlator 44, a demodulation unit 46, an FWT computing unit 50, a maximum value search unit 52, a storage unit 150, a second phase signal derivation unit 152, a phase signal determining unit 154 and a switch unit 60. Signals include a despread signal 204, a first phase correlation value signal 208, a first phase index signal 210, a second phase correlation value signal 212, a second phase index-signal 214 and a Walsh transform value FWT.

The equalizer 42 removes the effect of multipath transmission channel contained in the digital received signal 200. The equalizer 42 is constituted by a filter of transversal type. The equalizer 24 may be of such a structure that a DFE (Decision Feedback Equalizer) is added to the transversal-type filter.

To despread the phase-modulated signals which have been spread by a predetermined spread code such as a preamble or header region of a burst format shown in FIG. 1, the correlator 44 performs correlation processing on signals outputted from the equalizer 42 with said spread code. The correlation processing may be a sliding type correlation processing or a matched-filter type correlation processing. As described earlier, the correlator 44 operates in the regions of only “preamble” and “header” of a burst format as shown in FIG. 1. If, however, the data is a phase-modulated signal which has been spread by a predetermined spread code, the correlator 44 also operates even in the area of “data”.

The demodulation unit 46 demodulates the despread signals 204 which have been despread by the correlator 44. Since the modulation scheme used for despread signals 204 is DBPSK or DQPSK, the demodulation is carried out through differential detection.

The FWT computing unit 50 performs FWT computation on the CCK-modulated signals such as data regions of a burst format shown in FIG. 1, and outputs Walsh transform values FWT. More specifically, a chip signal in CCK modulation unit is inputted, and 64 Walsh transform values FWT, namely, 64 correlation values, are generated and outputted through correlation processing among chip signals.

The maximum value search unit 52 inputs the 64 Walsh transform values FWT and selects one Walsh transform value FWT based on the magnitude thereof. The maximum value search unit 52 then outputs the first phase correlation value signal 208 which is one selected Walsh transform value FWT and the first phase index signal 210 which indicates by the index number a combination composed of φ2 to φ4 corresponding to said selected Walsh transform value FWT. The first phase index signal 210 corresponds to a spread code signal in the first phase signal, and the first phase correlation value signal 208 corresponds to a differentially coded signal in the first phase signal.

The storage unit 150 stores the Walsh transform values FWT outputted from the FWT computing unit 50 in units of 64 thereof.

The second phase signal derivation unit 152 receives the input of a first phase index signal 210 and generates a second phase signal. Though a specific method for generating the second phase signal based on the first phase index signal 210 will be discussed 4later, the index number of a spread code signal corresponding to the second phase signal is generated as a second phase index signal 214, based on the index number indicated by the first phase index signal 210. The Walsh transform value FWT corresponding to the second phase signal is selected from among the Walsh transform values FWT stored in the storage unit 150 and then the thus selected Walsh transform value is outputted as a second phase correlation value signal 212.

The phase signal determining unit 154 selects either the first phase signal or the second phase signal. That is, if a difference between the magnitude of the first phase correlation value signal 208 and that of the second phase correlation value signal 212 is greater than or equal to a predetermined threshold value, the phase signal determining unit 154 selects the first phase signal. If, on the other hand, the difference therebetween is less than the predetermined threshold value, the first phase correlation value signal 208 and the second phase correlation value signal 212 are respectively subjected to the differential detection relative to an already outputted signal. The results of differential detection are respectively compared with the phases prior to differential coding. And the first phase signal or the second phase signal, whose error is smaller than the other, is selected. If the first phase signal is selected, a combination composed of a plurality of signals corresponding to the first phase index signal 210 and a signal obtained after subjecting the first phase correlation value signal 208 to differential detection are outputted. If, on the other hand, the second phase signal is selected, a combination composed of a plurality of signals corresponding to the second phase index signal 214 and a signal obtained after subjecting the second phase correlation value 212 to differential detection are outputted.

The switch unit 60 selects either a signal outputted from the demodulation unit 46 or a signal outputted from the phase signal determining unit 154, and outputs the selected signal as an output signal 202. For instance, in the duration of preamble and header regions in a burst format as shown in FIG. 1, the switch unit 60 selects the signal outputted from the demodulation unit 46 whereas in the duration of data region in the burst format it selects the signal outputted from the phase signal determining unit 154. And it outputs an inverted signal of the selected signal.

In terms of hardware, the above-described structure can be realized by a CPU, a memory and other LSIs of an arbitrary computer. In terms of software, it can be realized by memory-loaded programs which have managing and scheduling functions or the like, but drawn and described herein are function blocks that are realized in cooperation with those. Thus, it is understood by those skilled in the art that these function blocks can be realized in a variety of forms such as by hardware only, software only or the combination thereof.

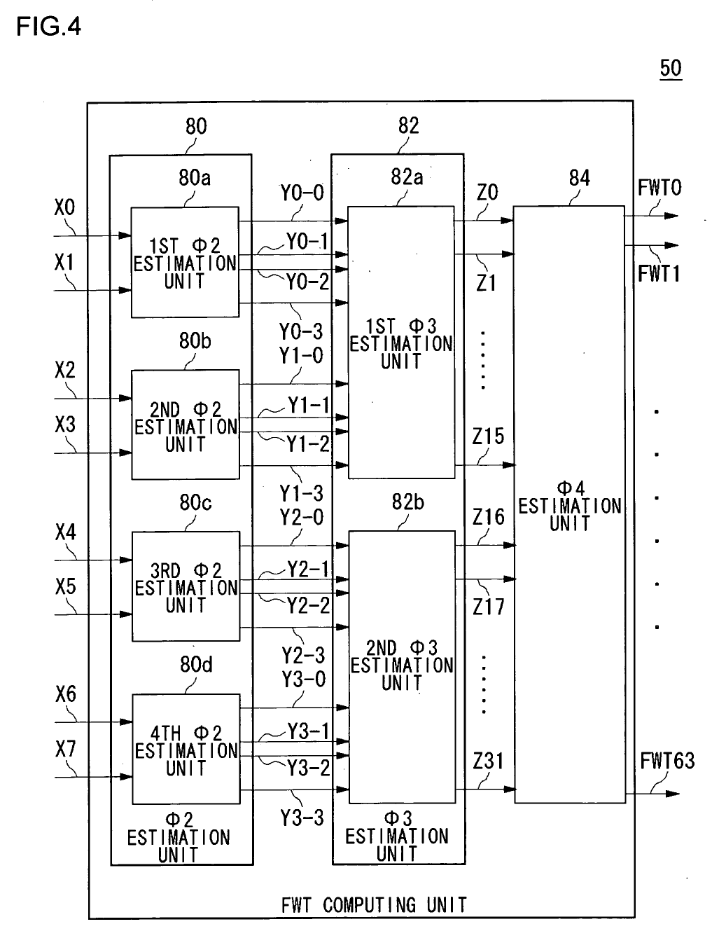

FIG. 4 illustrates a structure of an FWT computing unit 50. The FWT computing unit 50 includes a first φ2 estimation unit 80a, a second φ2 estimation unit 80b, a third φ2 estimation unit 80c and a fourth φ2 estimation unit 80d, which is generically referred to as a φ2 estimation unit 80, a first φ3 estimation unit 82a and a second φ3 estimation unit 82b, which is generically referred to as a φ3 estimation unit 82, and a φ4 estimation unit 84. Signals include Y0-0, Y0-1, Y0-2, Y0-3, Y1-0, Y1-1, Y1-2, Y1-3, Y2-0, Y2-1, Y2-2, Y2-3, Y3-0, Y3-1, Y3-2 and Y3-3, which are generically referred to as first correlation values Y, Z0, Z1, . . . , Z15, Z16, Z17, . . . and Z31, which are generically referred to as second correlation values Z, and FWT0, FWT1, . . . and FWT63, which are generically called Walsh transform values FWT.

The φ2 estimation unit 80 each inputs two chip signals X, for instance, X0 and X1. And it rotates the phase of X0 by 0, π/2, it and 3π/2, then adds the thus respectively rotated X0's to X1 and outputs Y0-0 to Y0-3, respectively. Here, in the case when the phase of the rotated X0 is equal to the phase of φ2, the magnitude of the first correlation value Y corresponding thereto becomes large. Using this result, φ2 can be estimated.

The φ3 estimation unit 82 operates the same way as the φ2 estimation unit 80. It inputs, for instance, Y0-0 to Y0-3 and Y1-0 to Y1-3 and outputs Z0 to Z15, respectively, so that φ3 can be estimated from the magnitude of the second correlation values Z. The φ4 estimation unit 84 operates the same way as the φ2 estimation unit 80. It inputs Z0 to Z31 and outputs FWT0 to FWT63, so that φ4 can be estimated from the magnitude of the Walsh transform values FWT.

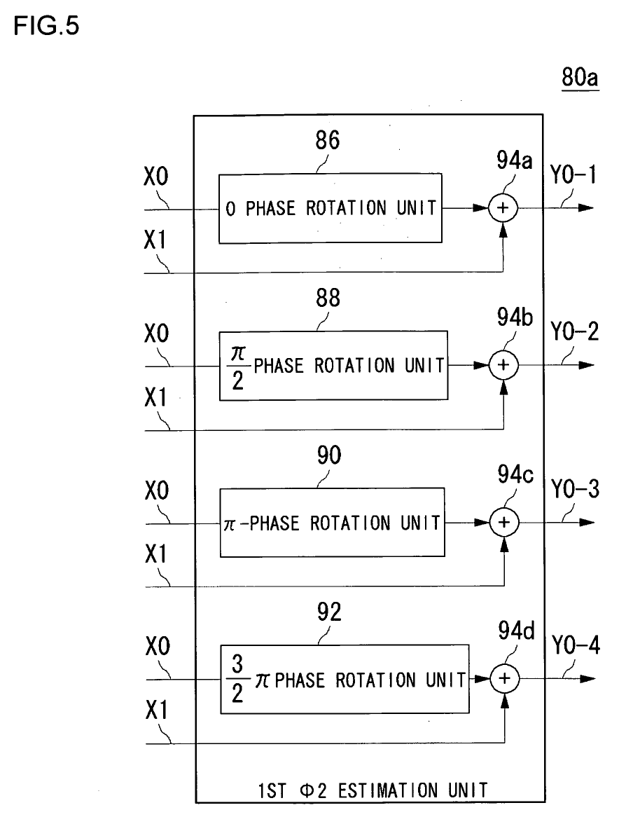

FIG. 5 illustrates a structure of the first φ2 estimation unit 80a. The first φ2 estimation unit 80a includes a 0 phase rotation unit 86, a π/2 phase rotation unit 88, a π phase rotation unit 90, a 3π/2 phase rotation unit 92, and a first adder 94a, a second adder 94b, a third adder 94c and a fourth adder 94d, which are generically referred to as adders 94.

The 0 phase rotation unit 86, π/2 phase rotation unit 88, π phase rotation unit 90, 3π/2 phase rotation unit 92 rotate the phase of X0 by 0, π/2, π and 3π/2, respectively. The output of such a rotation result is added with X1 in the adder 94.

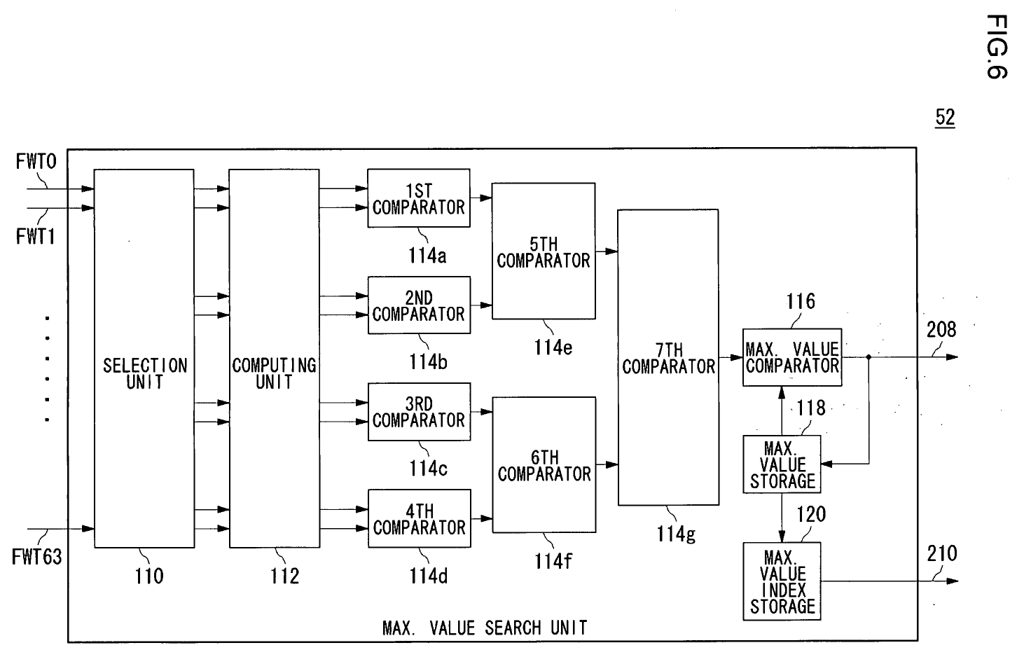

FIG. 6 illustrates a structure of the maximum value search unit 52. The maximum value search unit 52 includes a selection unit 110, a computing unit 112, a first comparator 114a, a second comparator 114b, a third comparator 114c, a fourth comparator 114d, a fifth comparator 114e, a sixth comparator 114f and a seventh comparator 114g, which are generically referred to as comparators 114, a maximum value comparator 116, a maximum value storage 118 and a maximum value index storage 120.

The selection unit 110 receives the input of 64 data composed of FWT0 to FWT63, and outputs 8 data at a time. For instance, FWT0 to FWT7 are outputted at the first timing and then FWT8 to FWT15 are outputted at the second timing.

The computing unit 112 computes Walsh transform values FWT, namely, the magnitude of FWT0 to FWT63. Here, if an in-phase component and a quadrature component of a Walsh transform value FWT are denoted by I and Q, respectively, then the magnitude R is obtained by the following Equation 3.
R=I²+Q² (Equation 3)

The comparators 114 compare eight R's and selects, per timing, a Walsh transform value FWT having the maximum value.

The maximum value comparator 116 compares the maximum value of Walsh transform values FWT outputted from the seventh comparator 114g, in units of 8 Walsh transform values FWT, with the maximum Walsh transform value FWT obtained so far, and selects the larger Walsh transform value FWT. The operation like this is executed in CCK modulation unit and the Walsh transform value FWT having the largest value among FWT0 to FWT63 is finally selected. The thus selected Walsh transform value FWT is stored in the maximum value storage 118.

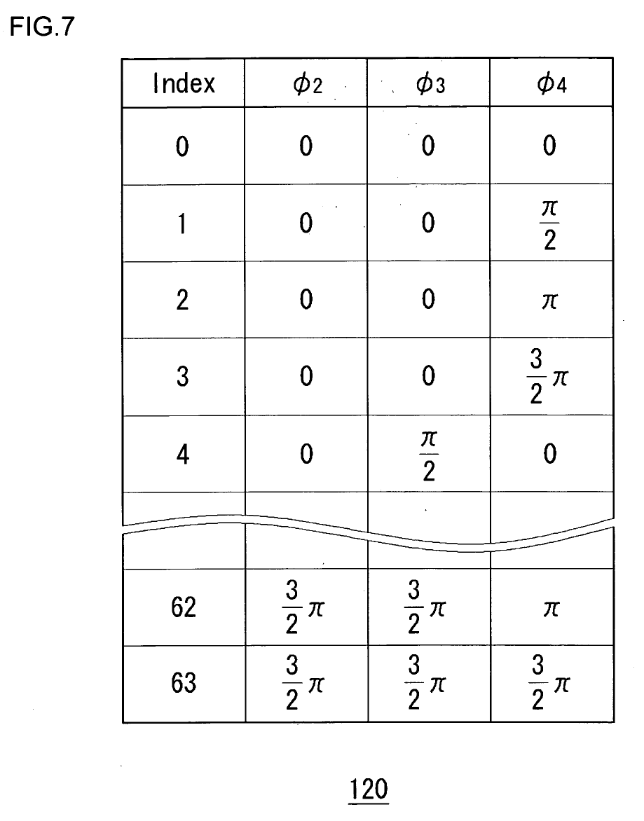

The maximum value index storage 120 selects the index number that corresponds to the Walsh transform value FWT stored finally in the maximum value storage 118, and outputs the selected index number as the first phase index signal 210. FIG. 7 illustrates a data structure of index which is set beforehand in the maximum value index storage 120. “0” to “63” are defined as indices having combinations each composed of phase φ2 to phase φ4.

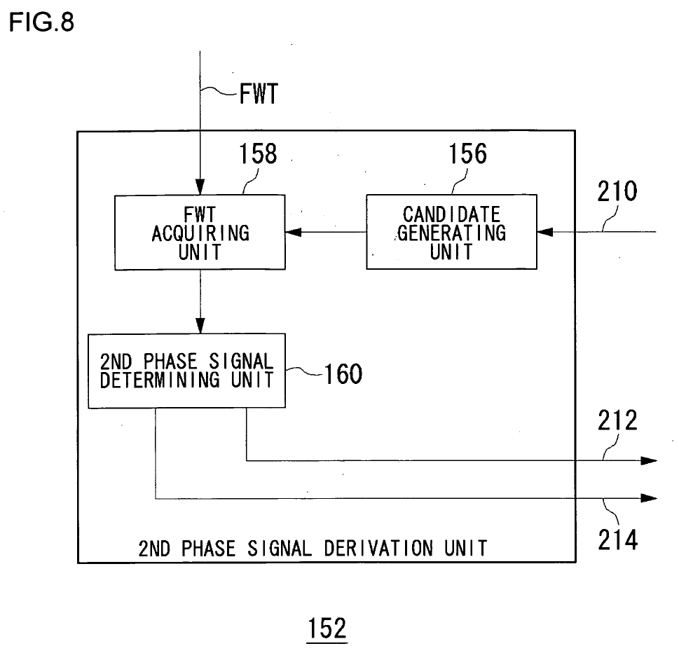

FIG. 8 illustrates a structure of the second phase signal derivation unit 152. The second phase signal derivation unit 152 includes a candidate generating unit 156, an FWT acquiring unit 158 and a second phase signal determining unit 160.

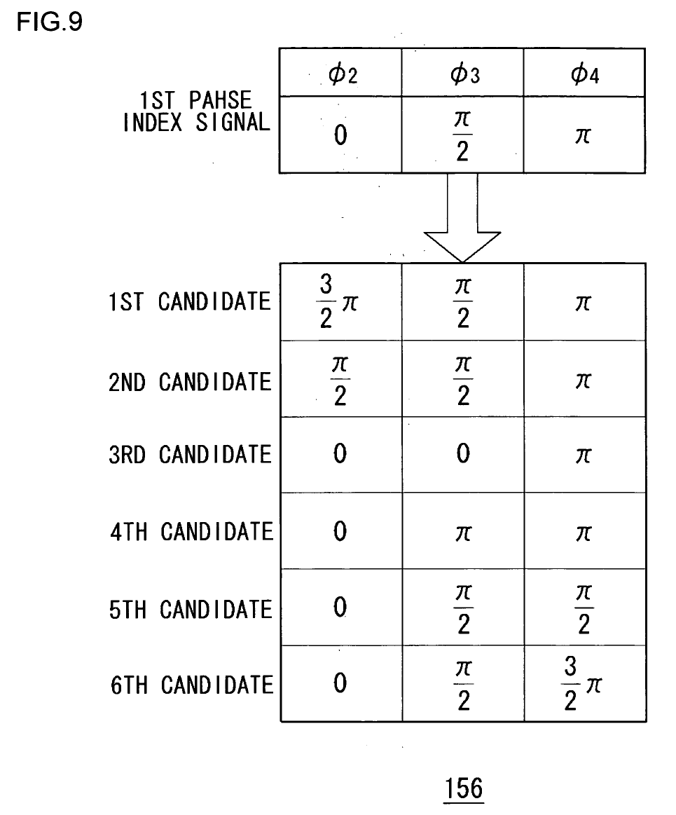

The candidate generating unit 156 receives the input of a first phase index signal 210 and generates, from the phase combination corresponding to the first phase index signal 210, candidates for a second phase signal, namely, first to sixth candidates. FIG. 9 shows the first to sixth candidates generated by the candidate generating unit 156. Here, “6” is inputted as the first phase index signal 210, and the values of phases φ2, φ3 and φ4 corresponding thereto are “0”, “π/2” and “π”, respectively. The candidate generating unit 156 rotates one of φ2, φ3 and φ4 by +π/2 or −π/2, and this rotation operation is applied to the rest of phases. Hence, the candidate generating unit 156 generates the six kinds of phase combinations, namely, the first to sixth candidates. For instance, the first candidate and the second candidate are generated with their φ2 being “3π/2” and “π/2”, respectively.

Referring back to FIG. 8, the FWT acquiring unit 158 acquires Walsh transform values FWT corresponding to the first to sixth candidates generated by the candidate generating unit 156. The second phase signal determining unit 160 compares the magnitudes of the Walsh transform values FWT corresponding to the first to sixth candidates, and selects the maximum Walsh transform value FWT. Then, one of the first to sixth candidates associated with the selected Walsh transform value FWT is determined as the second phase signal. The magnitude of the Walsh transform value FWT corresponding to the thus determined second phase signal is outputted as the second phase correlation value signal 212, and the index number corresponding to this second phase signal is outputted as the second phase index signal 214.

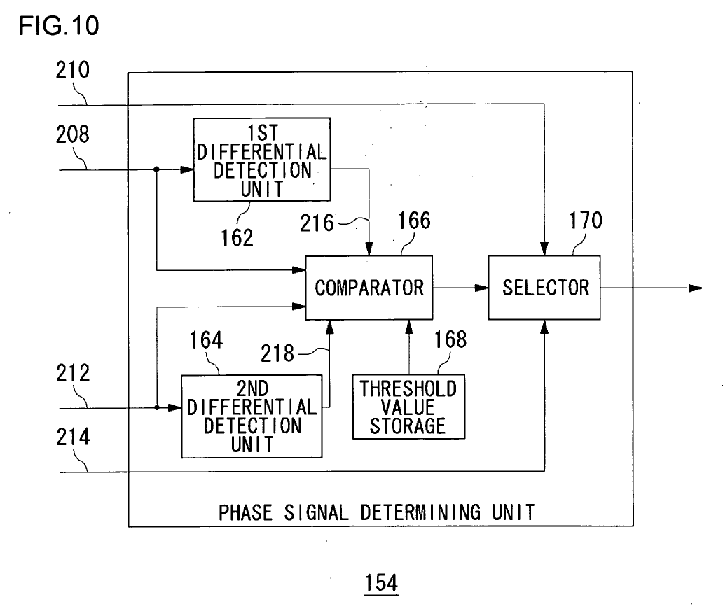

FIG. 10 illustrates a structure of the phase signal determining unit 154. The phase signal determining unit 154 includes a first differential detection unit 162, a second differential detection unit 164, a comparator 166, a threshold value storage 168 and a selector 170. Signals include a first differential detection signal 216 and a second differential detection signal 218.

The first differential detection unit 162 performs differential detection on the phase φ1 in the past which was selected by the comparator 166 and the first phase correlation value signal 208. Thus, the phase φ1 in the past is inputted to the first differential detection unit 162 from the comparator 166 via a-signal line which is not shown in FIG. 10. A result of this differential detection is outputted as the first differential detection signal 216. Here, the phase φ1 is DQPSK-modulated as described above. Thus, if there is no effect of noise or the like, the phase of the first differential detection signal 216 will be one of 0, π/2, π and 3π/2.

The second differential detection unit 164 performs differential detection on the phase φ1 in the past which was selected by the comparator 166 and the second phase correlation value signal 212. Thus, the phase φ1 in the past is inputted to the second differential detection unit 164 from the comparator 166 via a signal line which is not shown in FIG. 10. A result of this differential detection is outputted as the second differential detection signal 218. Similar to the first differential detection signal 216, if the phase of the second differential detection signal 218 is not affected by the noise or the like, it will be one of 0, π/2, π and 3π/2.

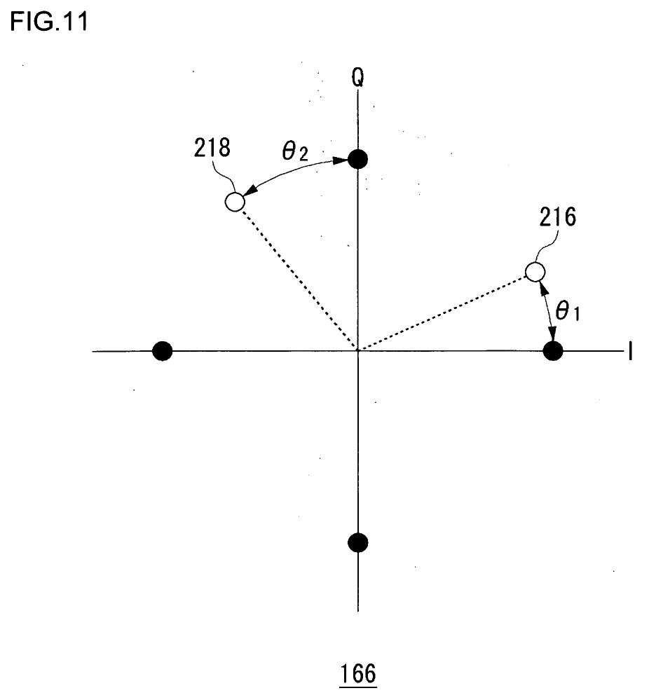

The comparator 166 subtracts the magnitude of the second phase correlation value signal 212 from that of the first phase correlation value signal 208. And if this subtraction result is greater than or equal to a threshold stored in the threshold value storage 168, the comparator 166 selects the first phase signal and, as a result thereof, outputs the first differential detection signal 216. If, on the other hand, the subtraction result is smaller than the threshold value, the following processing will be carried out. This processing will be described based on an operation scheme of the comparator 166 shown in FIG. 11. In FIG. 11, the phases 0, π/2, π and 3π/2 at which the differentially detected φ1 is supposed to be assigned are indicated by filled circles. The constellation of the first differential detection signal 216 and the second differential detection signal 218 is also shown in FIG. 11. The phase error between the phase of the first differential detection signal 216 and a phase, among 0, π/2, π and 3π/2, which approximates closest to the first differential detection signal 216 is denoted by θ1 whereas the phase error between the phase of the second differential detection signal 218 and a phase, among 0, π/2, π and 3π/2, which approximates closest to the second differential detection signal 218 is denoted by θ2.

The comparator 166 then compares the phase error θ1 with the phase error θ2. And if the phase error θ1 is smaller than θ2, the comparator 166 selects the first differential detection signal 216. If θ2 is smaller than θ1, it selects the second differential detection signal 218. The thus selected first differential detection signal 216 or the second differential detection signal 218 is outputted to the selector 170. Since the Walsh transform value FWT is obtained as a result of three-time correlation processings as in the FWT computing unit 50 of FIG. 4, the power value thereof is more amplified than the power value of a chip signal. In this manner, the above processing is meaningfully carried out since the phase obtained by performing differential detection on the thus amplified Walsh transform value FWT is accurate.

In accordance with the first differential detection signal 216 or the second differential detection signal 218 inputted from the comparator 166, the selector 170 outputs a signal corresponding thereto. That is, if the first differential detection signal 216 is inputted to the selector 170, [d1, d2], in which the first differential detection signal 216 has been determined, is combined with [d3, d4], [d5, d6] and [d7, d8] based on the first phase index signal 210 so as to output [d1, . . . , d8]. If, on the other hand, the second differential detection signal 218 is inputted to the selector 170, [d1, d2], in which the second differential detection signal 218 has been determined, is combined with [d3, d4], [d5, d6] and [d7, d8] based on the second phase index signal 214 so as to output [d1, . . . , d8].

An operation of the receiving apparatus 10 so structured as above will be described hereinbelow. In the duration of preamble and header regions, the correlator 44 despreads the signal which has been equalized by the equalizer 42, and the demodulation unit 46 demodulates the signal so as to output the output signal 202. In the duration of data, the FWT computing unit 50 performs FWT computation on the signals equalized by the equalizer 42 so as to obtain Walsh transform values FWT. The maximum value search unit 52 outputs the first phase correlation value signal 208 and the first phase index signal 210 as the first phase signal corresponding to the maximum Walsh transform value FWT, based on the magnitudes of Walsh transform values FWT. Based on the first phase index signal 210, the second phase signal derivation unit 152 generates, as the second phase signal, one of the first to sixth candidates in which one of φ2 to φ4 is rotated by +π/2 or −π/2.

Then the second phase correlation value signal 212 and the second phase index signal 214 which correspond to the second phase signal are outputted. The first differential detection unit 162 performs differential detection on the first phase correlation value signal 208 so as to output the first differential detection signal 216, and the second differential detection unit 164 performs differential detection on the second phase correlation value signal 212 so as to output the second differential detection signal 218. Since the difference between the magnitude of the first phase correlation value signal 208 and that of the second phase correlation value signal 212 is smaller than the threshold value stored in the threshold value storage 168, the comparator 166 compares respectively the phases of the first differential detection signal 216 and the second differential detection signal 218 with any one of 0, π/2, π and 3π/2 and obtains the errors. If the error in the second phase differential detection is smaller, a combination of signal corresponding to the second phase signal will be outputted.

According to the first embodiment, not only the magnitude in the resulting FWT computation but also the phases obtained after performing differential detection on the FWT computation result are taken into account in selecting the combination of phase signals, so that the combination of phase signals is selected accurately and therefore the receiving characteristics improve. Moreover, the second phase signal to be compared with the first phase signal which bears the maximum value in the FWT computation results can be generated by rotating any one of a plurality of phase signals contained in the first phase signal, so that a processing can be realized in a very simplified manner.

### Second Embodiment

Before describing the present invention in another specific manner, an outline thereof will be described. Similar to the first embodiment, a second embodiment according to the present invention relates to a receiving apparatus of wireless LAN system that conforms to the IEEE802.11b standard. A receiving apparatus according to the present embodiment receives signals in which a combination composed of a plurality of phase signals have been subjected to CCK modulation, and then derives a plurality of correlation values by an FWT computation. Then the receiving apparatus selects from among the plurality of correlation values a correlation value whose magnitude is the largest, and derives a combination of correlation signals corresponding to the thus selected correlation value. Hereinafter, the selected combination of correlation signals will be referred to as “first phase signal”. The combination of correlation signals contains four phase signals one of which is differentially coded. The remaining phase signals in the combination are respectively QPSK-modulated. Hereinafter these remaining phase signals will be collectively referred to as, or one of these phase signals will be referred to as “spread code signal”. In addition, the receiving apparatus selects a correlation value whose magnitude is the second largest, and derives a combination corresponding to the thus selected correlation value (hereinafter, the thus selected combination of phase signals will be referred to as “second phase signal”).

If a difference between the magnitude of a correlation value corresponding to the first phase signal and the magnitude of a correlation value corresponding to the second phase signal is greater than or equal to a threshold value, the differentially coded signal contained in the first phase is subjected to differential detection, and this signal which has been subjected to the differential detection and the spread code signal contained in the first phase signal are outputted. If, on the other hand, the difference between the magnitude of a correlation value corresponding to the first phase signal and the magnitude of a correlation value corresponding to the second phase signal is smaller than the threshold value, the signals respectively contained in the first phase signal and the second phase signal are respectively subjected to the differential detection, so that two kinds of differential detection results are obtained. If a phase in which the differential detection result is possibly assigned, for example, if the differential QPSK modulation is used as a differential coding, errors between each of the two kinds of differential detection results and any one of 0, π/2, π and 3π/2 (these phases will be hereinafter referred to as “phases prior to differential coding”) are respectively calculated. Among the thus calculated two kinds of errors, the first phase signal or the second phase signal corresponding to the error which is less than the other is selected. Finally, a spread code signal and a differential detection signal both corresponding to the thus selected phase signal are outputted.

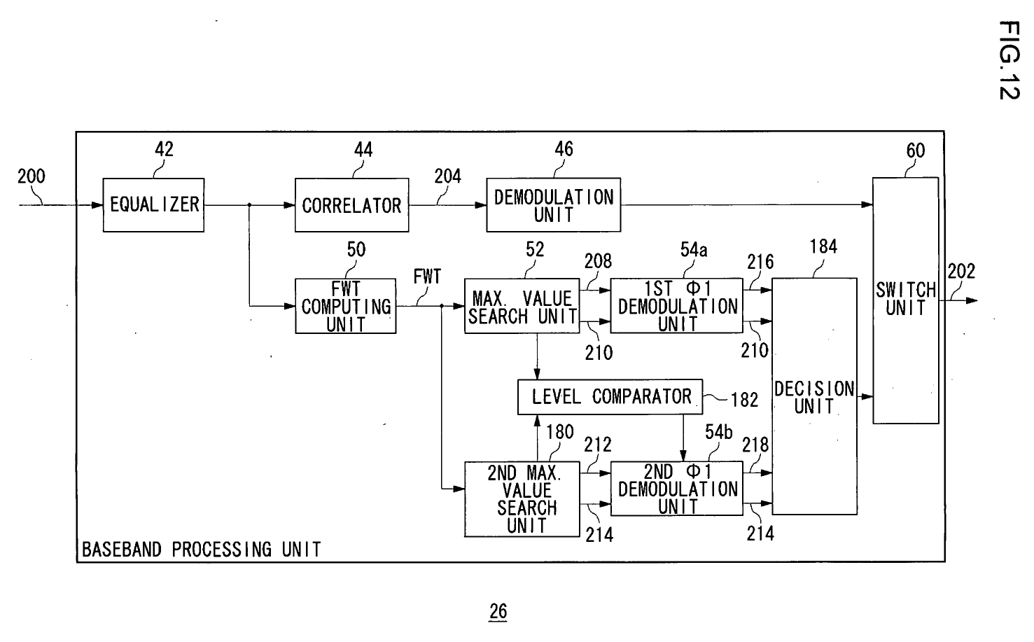

A communication system 100 according to the second embodiment is of the same type as the communication system 100 shown in FIG. 2, and the description thereof is omitted here. FIG. 12 illustrates a structure of a baseband processing unit 26. The baseband processing unit 26 includes an equalizer 42, a correlator 44, a demodulation unit 46, an FWT computing unit 50, a maximum value search unit 52, a first 41 demodulation unit 54a and a second 41 demodulation unit 54b, which are generically referred to as 41 demodulation units 54, a second maximum value search unit 180, a level comparator 182, a decision unit 184 and a switch unit 60. Signals involved here include a despread signal 204, a first phase correlation value signal 208, a first phase index signal 210, a second phase correlation value signal 212, a second phase index signal 214, a first differential detection signal 216, a second differential detection signal 218 and a Walsh transform value FWT.

The equalizer 42 eliminates the effect of multipath transmission channel contained in a digital received signal 200. The equalizer 42 is constituted by a filter of transversal type. The equalizer 24 may be of such a structure that a DFE (Decision Feedback Equalizer) is added to the transversal-type filter.

To despread the phase-modulated signals which have been spread by a predetermined spread code such as a preamble or header region of a burst format shown in FIG. 1, the correlator 44 performs correlation processing on signals outputted from the equalizer 42 with said spread code. The correlation processing may be a sliding type correlation processing or a matched-filter type correlation processing. As described earlier, the correlator 44 operates in the regions of only “preamble” and “header” of a burst format shown in FIG. 1. If, however, the data is a phase-modulated signal which has been spread by a predetermined spread code, the correlator 44 also operates even in the area of “data”.

The demodulation unit 46 demodulates despread signals 204 which have been despread by the correlator 44. Since the modulation scheme used for despread signals 204 is DBPSK or DQPSK, the demodulation is carried out through differential detection.

The FWT computing unit 50 performs FWT computation on the CCK-modulated signals such as data area of a burst format shown in FIG. 1, and outputs Walsh transform values FWT. More specifically, a chip signal in CCK modulation unit is inputted and 64 Walsh transform values FWT, namely, 64 correlation values, are generated and outputted through correlation processing among chip signals.

The maximum value search unit 52 inputs the 64 Walsh transform values FWT and selects one Walsh transform value FWT whose magnitude becomes maximum. The maximum value search unit 52 then outputs the first phase correlation value signal 208 which is one selected Walsh transform value FWT and the first phase index signal 210 which indicates by the index number a combination composed of φ2 to φ4 corresponding to said Walsh transform value FWT. The first phase index signal 210 corresponds to a spread code signal in the first phase signal, and the first phase correlation value signal 208 corresponds to a differentially coded signal in the first phase signal.

The second maximum value search unit 180 inputs the 64 Walsh transform values FWT and selects one Walsh transform value whose magnitude becomes the second largest. The second maximum value search unit 52 then outputs the second phase correlation value signal 212 which is one selected Walsh transform value FWT and the second phase index signal 214 which indicates by the index number a combination composed of φ2 to φ4 corresponding to said Walsh transform value FWT. The second phase index signal 214 corresponds to a spread code signal in the second phase signal, and the second phase correlation value signal 212 corresponds to a differentially coded signal in the second phase signal. Here, information on the first phase signal may be transmitted from the maximum value search unit 52 to the second maximum value search unit 180 via a signal line which is not shown, and one Walsh transform value FWT whose magnitude becomes maximum may be selected from among 63 Walsh transform values FWT excluding the Walsh transform value FWT that corresponds to the first phase signal.

The level comparator 182 compares the difference between the magnitude of the first phase correlation value signal 208 outputted from the maximum value search unit 52 and the magnitude of the second phase correlation value signal 212 outputted from the second maximum value search unit 180 with a predetermined threshold value. If this error is greater than or equal to the threshold value, the operation of the second φ1 demodulation unit 54b is stopped so that an 8-bit signal in CCK modulation unit contained in the first phase signal is outputted. If, on the other hand, the error is smaller than the threshold value, the second φ1 demodulation unit 54b is operated so that one of the first phase signal and the second phase signal is selected by the decision unit 184.

The first 41 demodulation unit 54a performs differential detection on the phase φ1, which was selected in the past by the decision unit 184, and the first phase correlation value signal 208. Thus, the phase φ1 in the past is inputted to the first φ1 demodulation unit 54a from the decision unit 184 via a signal line which is not shown in FIG. 12. A result of this differential detection is outputted as a first differential detection signal 216. Since the phase φ1 is DQPSK-modulated as described above, the phase of the first differential detection signal 216 will be any one of 0, π/2, π and 3π/2 if it is not affected by the noise or the like. Although the first phase index signal 210 is also inputted to the first φ1 demodulation unit 54a, the first phase index signal 210 inputted thereto is outputted as it is.

The second 41 demodulation unit 54b performs differential detection on the phase φ1, which was selected in the past by the decision unit 184, and the second phase correlation value signal 212. Thus, the phase φ1 in the past is inputted to the second demodulation unit 54b from the decision unit 184 via a signal line which is not shown in FIG. 12. A result of this differential detection is outputted as a second differential detection signal 218. Similar to the first differential detection signal 216, if it is not affected by the noise or the like, the phase of the second differential detection signal 218 will be any one of 0, π/2, π and 3π/2. The second phase index signal 214 is also inputted to the second, φ1 demodulation unit 54b and is then outputted as it is.

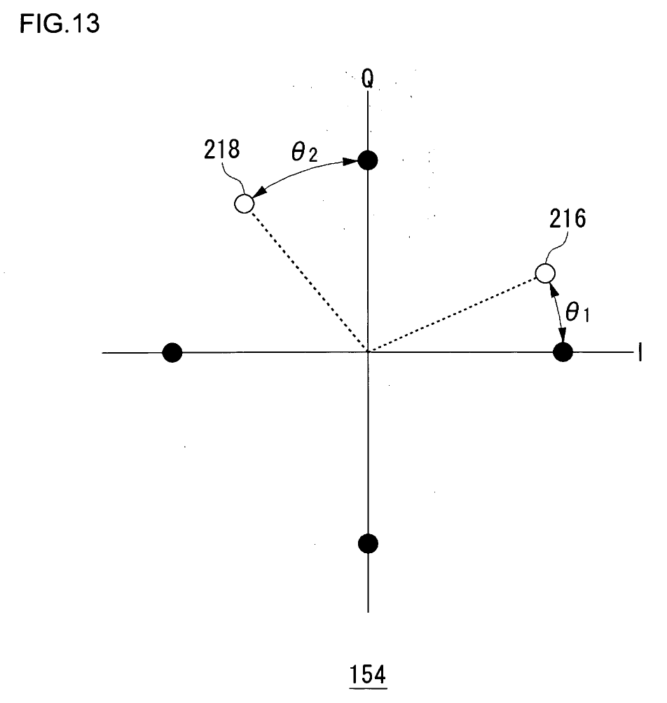

The decision unit 184 selects either the first phase signal or the second phase signal, based on the first differential detection signal 216 and the second differential detection signal 218. This selection processing will be described based on an operation scheme of the comparator 166 shown in FIG. 13. In FIG. 13, the phases 0, π/2, π and 3π/2 at which the differentially detected φ1 is supposed to be assigned are indicated by filled circles. The constellation of the first differential detection signal 216 and the second differential detection signal 218 is also shown in FIG. 13. The phase error between the phase of the first differential detection signal 216 and a phase, among 0, π/2, and 3π/2, which approximates closest to the first differential detection signal 216 is denoted by θ1 whereas the phase error between the phase of the second differential detection signal 218 and a phase, among 0, π/2, π and 3π/2, which approximates closest to the second differential detection signal 218 is denoted by θ2. The decision unit 184 compares the phase error θ1 with the phase error θ2. And if the phase error θ1 is smaller than θ2, the decision unit 184 selects the first differential detection signal 216. If θ2 is smaller than θ1, it selects the second differential detection signal 218. Since the Walsh transform value FWT is obtained as a result of three-time correlation processings as will be described in detail later, the power value thereof is more amplified than the power value of a chip signal. In this manner, the above processing is meaningfully carried out since the phase obtained by performing differential detection on the thus amplified Walsh transform value FWT is accurate.

In accordance with the selected first differential detection signal 216 or second differential detection signal 218, the decision unit 184 outputs a signal corresponding thereto. That is, if the first differential detection signal 216 is selected, [d1, d2], in which the first differential detection signal 216 has been determined, is combined with [d3, d4], [d5, d6] and [d7, d8] based on the first phase index signal 210 so as to output [d1, . . . , d8]. If, on the other hand, the second differential detection signal 218 is selected, [d1, d2], in which the second differential detection signal 218 has been determined, is combined with [d3, d4], [d5, d6] and [d7, d8] based on the second phase index signal 214 so as to output [d1, . . . , d8].

The switch unit 60 selects either a signal outputted from the demodulation unit 46 or a signal outputted from the decision unit 184, and outputs the selected signal as an output signal 202. For instance, in the duration of preamble and header regions in a burst format as shown in FIG. 1, the switch unit 60 selects the signal outputted from the demodulation unit 46 whereas in the duration of data region in the burst format it selects the signal outputted from the decision unit 184. And it outputs an inverted signal of the selected signal.

An FWT computing unit 50, a first φ2 estimation unit 80a and a maximum value search unit 52 according to the second embodiment are of the same type as the FWT computing unit 50, the first φ2 estimation unit 80a and the maximum value search unit 52 shown in FIG. 4, FIG. 5 and FIG. 6, respectively. The second maximum value search unit 180 is structured the same way as the maximum value search unit 52, and the second maximum value search unit 180 operates the same way as the maximum value search unit 52 except for the first phase signal.

An operation of the receiving apparatus 10 so structured as above will be described hereinbelow. In the duration of preamble and header regions, the correlator 44 despreads the signal which has been equalized by the equalizer 42, and the demodulation unit 46 demodulates the signal so as to output the output signal 202. In the duration of data, the FWT computing unit 50 performs FWT computation on the signals equalized by the equalizer 42 so as to obtain Walsh transform values FWT. The maximum value search unit 52 outputs the first phase correlation value signal 208 and the first phase index signal 210 as the first phase signal corresponding to the maximum Walsh transform value FWT, based on the magnitudes of Walsh transform values FWT. The second maximum value search unit 180 outputs the second phase correlation value signal 210 and the second phase index signal 214 as the second phase signal corresponding to the second largest Walsh transform value FWT.

The level comparator 182 compares the magnitude of the first phase correlation value signal 208 with the magnitude of the second phase correlation value signal 212. And if the difference therebetween is smaller than the threshold value, both the first φ1 demodulation unit 54a and the second φ1 demodulation unit 54b are operated. The first φ1 demodulation unit 54a performs differential detection on the first phase correlation value signal 208 so as to output the first differential detection signal 216. The second φ1 demodulation unit 54b performs differential detection on the second phase correlation value signal 212 so as to output the second differential detection signal 218. The decision unit 184 compares the phases of the first differential detection signal 216 and the second differential detection signal 218 with any one of 0, π/2, π and 3π/2, respectively, so as to obtain errors. If the error of the second differential detection signal 218 is smaller, a combination corresponding to the second phase signal is outputted.

According to the second embodiment, not only the magnitude in the resulting FWT computation but also the phases obtained after performing differential detection on the FWT computation result are taken into account in selecting the combination of phase signals, so that the combination of phase signals is selected accurately and therefore the receiving characteristics improve. Moreover, the second phase signal, having the second largest magnitude, obtained as a result of the FWT computation result is also treated as an object to be processed, and it is highly probable that the second phase signal is inverted relative to the first phase signal due to the noise and the like, so that the accurate selection of a combination of phase signals is realized.

### Third Embodiment

Similar to the second embodiment, a third embodiment is such that a first phase signal and a second phase signal are selected based on the respective magnitudes of a plurality of correlation values obtained through FWT computation. In the second embodiment, a signal bearing a correlation value whose magnitude is the largest is selected as the first phase signal whereas a signal bearing a correlation value whose magnitude is the second largest is selected as the second phase signal. In the third embodiment, however, a signal or signals whose correlation values are greater than or equal to a predetermined threshold value are selected as the second phase signal. That is, the number of the second phase signals is not necessarily one but may be plural.

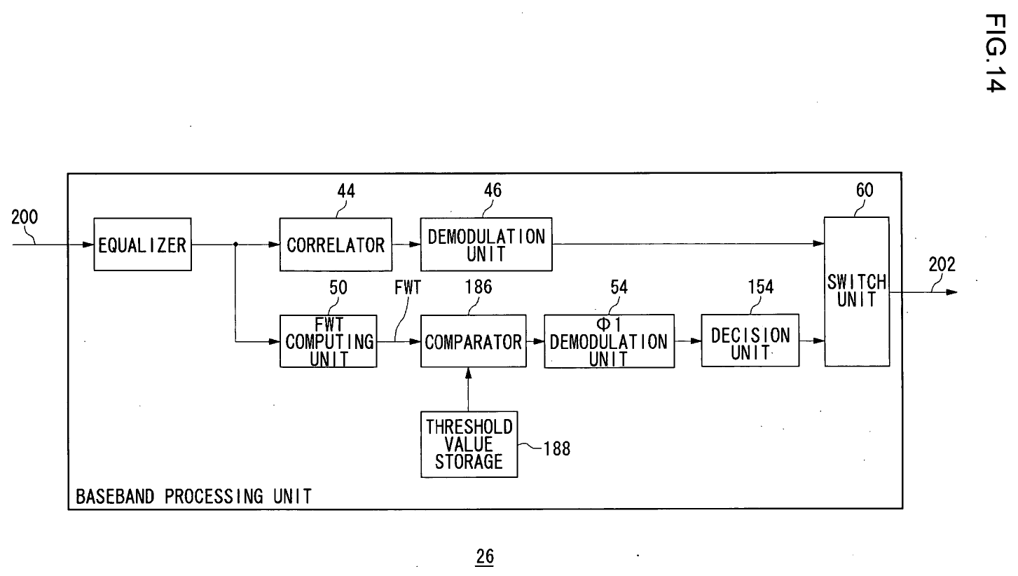

FIG. 14 illustrates a structure of a baseband processing unit 26 according to the third embodiment. In the baseband processing unit 26 shown in FIG. 14, a comparator 186 and a threshold value storage 188 are newly added and the maximum value search unit 52, the second maximum value search unit 180 and the level comparator 182 are eliminated in comparison with the baseband processing unit 26 shown in FIG. 12.

The comparator 186 is structured the same way as the maximum value search unit 52. And a Walsh transform value FWT whose magnitude is the largest is selected from among 64 Walsh transform values outputted from the FWT computing unit 50, and a first phase signal corresponding to the thus selected Walsh transform value FWT is derived. The comparator 186 compares the magnitude of the remaining 63 Walsh transform values FWT with a threshold value stored in the threshold value storage 188, selects a single or plurality of Walsh transform values FWT whose magnitude is/are greater than or equal to the threshold value, and selects the second phase signal corresponding to the thus selected single or plurality of Walsh transform values FWT. It is to be noted here that if there are a plurality of Walsh transform values FWT whose magnitudes are greater than or equal to the threshold value, then there are the plurality of second phase signals.

In a φ1 demodulation unit 54 and a decision unit 154, as already described in the second embodiment, a combination composed of a plurality of signals are selected from the first phase signal and the second phase signal. However, since there are cases where a plurality of second phase signals exist, the φ1 demodulation unit 54 and the decision unit 154 are so structured as to cope with these cases.

According to the third embodiment, not only the magnitude in the resulting FWT computation but also the phases obtained after performing differential detection on the FWT computation result are taken into account in selecting the combination of phase signals, so that the combination of phase signals is selected accurately and therefore the receiving characteristics improve. Moreover, all of the second phase signals, which have the magnitude greater than or equal to the predetermined threshold value, obtained as a result of the FWT computation result are also treated as objects to be processed, so that the accurate selection of a combination of phase signals is realized.

The present invention has been described based on the embodiments which are only exemplary. It is therefore understood by those skilled in the art that other various modifications to the combination of each component and process described above are possible and that such modifications are also within the scope of the present invention.

In the first to third embodiments, the computing unit 112 computes the magnitude R of Walsh transform values FWT. However, the modes of carrying out the present invention are not limited thereto. For example, the summation of absolute values may be obtained. Or, an approximate value R for the magnitude of Walsh transform values FWT as expressed in the following Equation 4 may be evaluated.
R=A1×Max{|I|, |Q|}+A2×Min{|I|, |Q|} (Equation 4)
where A1 and A2 are arbitrary values.

Furthermore, the error between the phase of a Walsh transform value FWT and any one of phases at which the Walsh code is allocated is calculated, and if the error becomes smaller, then the factor whose value becomes larger is calculated. The approximate value R may be evaluated in a manner such that the sum of squares of I and Q of Walsh transform values FWT is multiplied by the factor. In such cases, a phase correcting circuit which corrects the absolute phase of a digital received signal 200 or an output signal of the equalizer 42 may be additionally provided in the baseband processing unit 26.

According to this modification, the receiving characteristics further improve. That is, it suffices if the magnitude of approximate value R becomes larger as the phase of a Walsh transform value FWT approaches the any one of phases at which the Walsh code is allocated.

Although the present invention has been described by way of exemplary embodiments and modifications, it should be understood that many other changes and substitutions may further be made by those skilled in the art without departing from the scope of the present invention which is defined by the appended claims.

What is claimed is:

1. A receiving apparatus, comprising:
a receiver which receives a signal indicative of at least one symbol including a plurality of Walsh codes wherein the plurality of Walsh codes are generated based on a combination composed of a plurality of phase signals that contain differentially coded phase signals;
a Walsh transform unit which performs Walsh transform on the signal received by said receiver for each symbol and which then generates a plurality of correlation values;
a first derivation unit which selects a single correlation value based on the magnitude of the plurality of correlation values generated by said Walsh transform unit and which derives, as a first phase signal, a combination composed of a plurality of phase signals corresponding to the selected correlation value;
a second derivation unit which derives, as a second phase signal, a combination composed of a plurality of phase signals other than a plurality of phase signals corresponding to the first phase signal; and
an output unit which outputs the plurality of phase signals corresponding to either the first phase signal or second phase signal, based on the differentially coded phase signals contained respectively in the first phase signal derived by said first derivation unit and the second phase signal derived by said second derivation unit.

2. A receiving apparatus, comprising:
a receiver which receives a signal indicative of at least one symbol including a plurality of Walsh codes wherein the plurality of Walsh codes are generated based on a combination composed of a plurality of phase signals that contain differentially coded phase signals;
a Walsh transform unit which performs Walsh transform on the signal received by said receiver for each symbol and which then generates a plurality of correlation values;
a first derivation unit which selects a single correlation value based on the magnitude of the plurality of correlation values generated by said Walsh transform unit and which derives, as a first phase signal, a combination composed of a plurality of phase signals corresponding to the selected correlation value;
a second derivation unit which derives, as a second phase signal, a combination composed of a plurality of phase signals other than a plurality of phase signals corresponding to the first phase signal, based on the first phase signal derived by said first derivation unit; and
an output unit which outputs the plurality of phase signals corresponding to either the first phase signal or second phase signal, based on the differentially coded phase signals contained respectively in the first phase signal derived by said first derivation unit and the second phase signal derived by said second derivation unit.

3. A receiving apparatus according to claim 2, wherein said second derivation unit comprises:
a candidate generating unit which rotates any of phase of a plurality of phase signals other than the differentially coded phase signals, among the combination comprised of a plurality of phase signals corresponding to the first phase signal derived by said first derivation unit and which generates a plurality of candidates for the second phase signal by changing a phase signal, whose phase is to be rotated, among the plurality of phase signals; and
a selector which selects the second phase signal based on the magnitude of correlation values corresponding respectively to the plurality of generated candidates for the second phase signal.

4. A receiving apparatus according to claim 3, wherein said candidate generating unit rotates a phase of the phase signal, whose phase is to be rotated, up to a phase adjacent to a primarily assigned phase among a plurality of phases to which a phase signal is possibly assigned, and then generates a candidate for the second phase signal.

5. A receiving apparatus according to claim 2, further comprising a managing unit which manages the combination composed of a plurality of phase signals by an identification number,
wherein said first derivation unit derives from said managing unit an identification number corresponding to the first phase signal and
wherein said second derivation unit derives from said managing unit an identification number corresponding to the second phase signal, based on the derived identification number corresponding to the first phase signal.

6. A receiving apparatus, comprising:
a receiver which receives a signal indicative of at least one symbol including a plurality of Walsh codes wherein the plurality of Walsh codes are generated based on a combination composed of a plurality of phase signals that contain differentially coded phase signals;
a Walsh transform unit which performs Walsh transform on the signal received by said receiver for each symbol and which then generates respectively a plurality of correlation values;
a first derivation unit which selects a single correlation value based on the magnitude of the plurality of correlation values generated by said Walsh transform unit and which derives, as a first phase signal, a combination composed of a plurality of phase signals corresponding to the selected correlation value;
a second derivation unit which derives, as a second phase signal, a combination composed of a plurality of phase signals other than a plurality of phase signals corresponding to the first phase signal, based on the magnitude of the plurality of correlation values generated by said Walsh transform unit; and
an output unit which outputs the plurality of phase signals corresponding to either the first phase signal or second phase signal, based on the differentially coded phase signals contained respectively in the first phase signal derived by said first derivation unit and the second phase signal derived by said second derivation unit.

7. A receiving apparatus according to claim 6, wherein said first derivation unit selects a correlation value whose magnitude is maximum among the plurality of correlation values generated by said Walsh transform unit and derives, as the first phase signal, a combination composed of a plurality of phase signals corresponding to the selected correlation value, and wherein said second derivation unit selects a correlation value whose magnitude is largest next to the correlation value selected by said first derivation unit among the plurality of correlation values generated by said Walsh transform unit and derives, as the second phase signal, a combination composed of a plurality of phase signals corresponding to the selected correlation value.

8. A receiving apparatus according to claim 6, wherein said second derivation unit selects a correlation value whose magnitude is greater than or equal to a predetermined threshold value and derives, as the second phase signal, a combination composed of a plurality of phase signals corresponding to said selected value.

9. A receiving apparatus according to claim 2, wherein said output unit outputs a plurality of phase signals corresponding to the first phase signal if a difference between the magnitude of a correlation value corresponding to the derived first phase signal and that corresponding to the derived second phase signal is greater than or equal to a predetermined threshold value.

10. A receiving apparatus according to claim 6, wherein said output unit outputs a plurality of phase signals corresponding to the first phase signal if a difference between the magnitude of a correlation value corresponding to the derived first phase signal and that corresponding to the derived second phase signal is greater than or equal to a predetermined threshold value.

11. A receiving apparatus according to claim 2, wherein said output unit includes:
a differential detection unit which respectively performs differential detection on differentially coded phase signal among a plurality of phase signals outputted in the past from said output unit for differentially coded phase signals contained in the first phase signal derived by said first derivation unit, and the second phase signal derived by said second derivation unit, respectively; and
a comparator which compares differential detection results and selects either the first phase signal or the second phase signal.

12. A receiving apparatus according to claim 6, wherein said output unit includes:
a differential detection unit which respectively performs differential detection on differentially coded phase signal among a plurality of phase signals outputted in the past from said output unit for differentially coded phase signals contained in the first phase signal derived by said first derivation unit and the second phase signal derived by said second derivation unit, respectively; and
a comparator which compares differential detection results and selects either the first phase signal or the second phase signal.

13. A receiving apparatus according to claim 11, wherein said comparator performs differential detection on differentially coded phase signals in the derived first phase signal and the derived second phase signal, compares the differential detection result with a phase to which a signal is possibly assigned, and selects either the first phase signal or the second phase signal.

14. A receiving apparatus according to claim 12, wherein said comparator performs differential detection on differentially coded phase signals in the derived first phase signal and the derived second phase signal, compares the differential detection result with a phase to which a signal is possibly assigned, and selects either the first phase signal or the second phase signal.

15. A receiving method, comprising:
receiving a signal indicative of at least one symbol including a plurality of Walsh codes wherein the plurality of Walsh codes are generated based on a combination composed of a plurality of phase signals that contain differentially coded phase signals;
performing Walsh transform on the signal received by said receiving for each symbol and generating respectively a plurality of correlation values;
selecting a single correlation value based on the magnitude of the plurality of correlation values generated by said performing and generating, and deriving, as a first phase signal, a combination composed of a plurality of phase signals corresponding to the selected correlation value;
deriving, as a second phase signal, a combination composed of a plurality of phase signals other than a plurality of phase signals corresponding to the first phase signal; and
outputting the plurality of phase signals corresponding to either the first phase signal or second phase signal, based on the differentially coded phase signals contained respectively in the first phase signal derived by said selecting and deriving and the second phase signal derived by said deriving.

16. A receiving method, comprising:
receiving a signal indicative of at least one symbol including a plurality of Walsh codes wherein the plurality of Walsh codes are generated based on a combination composed of a plurality of phase signals that contain differentially coded phase signals;
performing Walsh transform on the signal received by said receiving for each symbol and generating respectively a plurality of correlation values;
selecting a single correlation value based on the magnitude of the plurality of correlation values generated by said performing and generating, and deriving, as a first phase signal, a combination composed of a plurality of phase signals corresponding to the selected correlation value;
deriving, as a second phase signal, a combination composed of a plurality of phase signals other than a plurality of phase signals corresponding to the first phase signal, based on the first phase signal derived by said selecting and deriving; and
outputting the plurality of phase signals corresponding to either the first phase signal or second phase signal, based on the differentially coded phase signals contained respectively in the first phase signal derived by said selecting and deriving and the second phase signal derived by said deriving.

17. A receiving method, comprising:
receiving a signal indicative of at least one symbol including a plurality of Walsh codes wherein the plurality of Walsh codes are generated based on a combination composed of a plurality of phase signals that contain differentially coded phase signals;
performing Walsh transform on the signal received by said receiving for each symbol and generating respectively a plurality of correlation values;
selecting a single correlation value based on the magnitude of the plurality of correlation values generated by said performing and generating, and deriving, as a first phase signal, a combination composed of a plurality of phase signals corresponding to the selected correlation value;
deriving, as a second phase signal, a combination composed of a plurality of phase signals other than a plurality of phase signals corresponding to the first phase signal, based on the magnitude of the plurality of correlation values generated by said performing and generating; and
outputting the plurality of phase signals corresponding to either the first phase signal or second phase signal, based on the differentially coded phase signals contained respectively in the first phase signal derived by said selecting and deriving and the second phase signal derived by said deriving.
